(19) United States
(12) Patent Application Publication
(10) Pub. No.: US 2019/0363254 A1
(43) Pub. Date: Nov. 28, 2019

(54) FILM FORMATION DEVICE, FILM FORMATION METHOD, ELECTRONIC DEVICE, AND MANUFACTURING DEVICE OF ELECTRONIC DEVICE

(71) Applicant: Sharp Kabushiki Kaisha, Sakai City, Osaka (JP)

(72) Inventor: Masaki HIRUOKA, Sakai City (JP)

(21) Appl. No.: 16/068,682

(22) PCT Filed: Mar. 30, 2017
(86) PCT No.: PCT/JP2017/013354

§ 371 Date: Jul. 9, 2018

(51) Int. Cl. H01L 51/00; H01L 51/52; B41J 2/01; B05D 1/26; H01L 51/56

(52) U.S. Cl. CPC H01L 51/0005; H01L 51/524; H01L 51/56; B05D 1/26; B41J 2/01

(57) ABSTRACT

A film formation device includes an ejecting portion that ejects a first droplet material, and an ejecting portion that ejects a second droplet material having a viscosity greater than a viscosity of the first droplet material. The first and the second droplet materials, upon ejection, form a first film formed by application of the first droplet material and a second film formed by application of the second droplet material, the first film and the second film being adjacent to each other on a surface of an object to be coated.

### TECHNICAL FIELD

The disclosure relates to a film formation method and a film formation device based on an inkjet method, and particularly relates to a manufacturing method and a manufacturing device of an electroluminescent (EL) device that includes an EL layer.

### BACKGROUND ART

PTL 1 discloses a method for manufacturing an EL device by a manufacturing device that includes an inkjet head provided with a plurality of ejecting nozzles that eject ink containing an organic material.

### CITATION LIST

### Patent Literature

PTL 1: JP 2009-141285 A (published on Jun. 25, 2009)

### SUMMARY

### Technical Problem

An object of a first aspect of the disclosure is to achieve a film formation method and a film formation device that, when forming a film by an inkjet method, readily control a formation range of the film.

### Solution to Problem

To solve the above-described problems, a film formation device according to a first aspect of the disclosure is based on an inkjet method, and includes a first ejecting portion that ejects a first droplet material, and a second ejecting portion that ejects a second droplet material having a viscosity greater than a viscosity of the first droplet material. The first and the second droplet materials, upon ejection, form a first film formed by application of the first droplet material and a second film formed by application of the second droplet material, the first film and the second film being adjacent to each other on a surface of an object to be coated.

A film formation method according to the first aspect of the disclosure is based on an inkjet method, and includes a first ejecting step of ejecting a first droplet material, and a second ejecting step of ejecting a second droplet material having a viscosity greater than a viscosity of the first droplet material. The first and the second droplet materials, upon ejection, form a first film formed by application of the first droplet material and a second film formed by application of the second droplet material, the first film and the second film being adjacent to each other on a surface of an object to be coated.

An electronic device according to the first aspect of the disclosure includes a circuit substrate provided with a first film formed by applying a first droplet material and a second film formed by applying a second droplet material having a viscosity greater than a viscosity of the first droplet material, the first film and the second film formed adjacent to each other in a direction along a substrate surface.

### Advantageous Effects of Disclosure

According to the disclosure, it is possible to control a formation range of a film by an inkjet method.

### BRIEF DESCRIPTION OF DRAWINGS

FIGS. 1A and 1B are flowcharts illustrating an example of a manufacturing method of an EL device.

FIG. 2A is a cross-sectional view illustrating a configuration example of the EL device, and FIG. 2B is a cross-sectional view illustrating a configuration example midway through the manufacture of the EL device.

FIG. 3 is a cross-sectional view illustrating a non-active region NA of the EL device.

FIG. 4 is a plan view illustrating a plurality of EL devices formed into a matrix on a surface of a base material.

FIG. 5 is a perspective view illustrating an outer appearance of a film formation device that forms a film on the EL device.

FIG. 6 is a diagram illustrating application regions of an ink A and an ink B.

FIG. 7 is a cross-sectional view of the film formation device.

FIG. 8 is a cross-sectional view of a tip of an ejecting portion of the film formation device.

FIG. 9 is a block diagram illustrating a configuration of an EL device manufacturing device.

### DESCRIPTION OF EMBODIMENTS

### First Embodiment

A detailed description follows regarding embodiments of the disclosure. A film formation device according to a first embodiment of the disclosure can be applied not only to the manufacture of a light emitting element of an organic electroluminescent (EL) display including an organic light emitting diode (OLED), an inorganic EL display including an inorganic light emitting diode, or the like, but also to the manufacture of a quantum dot light emitting diode (QLED) display including a QLED. According to the film formation device, a film can be formed without requiring a vacuum step, and thus significant improvements in productivity can be expected. In the following, description will be made using as an example a film formation device configured to manufacture an organic EL device that includes an OLED.

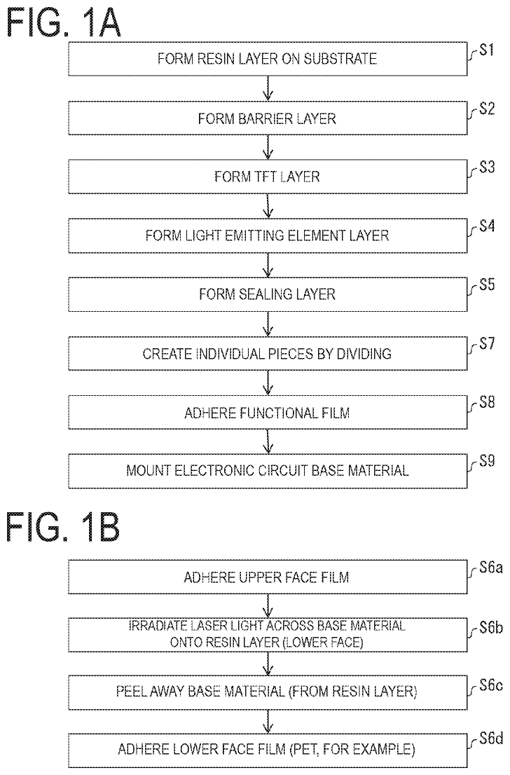

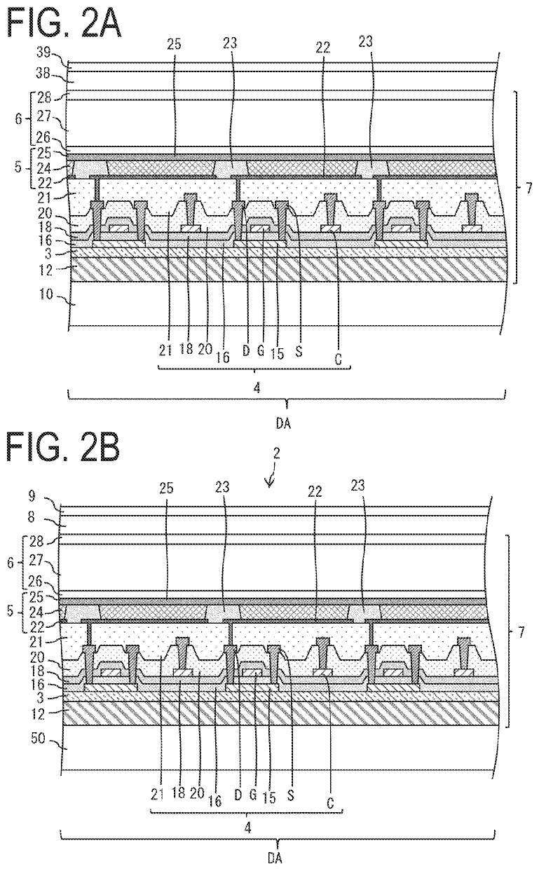

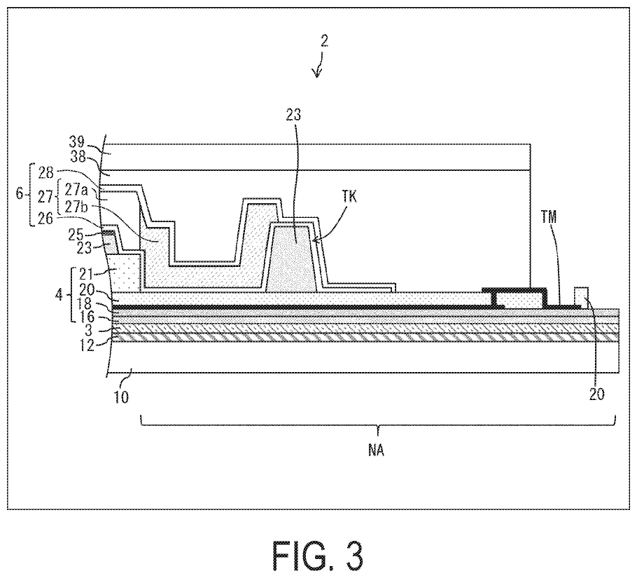

FIGS. 1A and 1B are flowcharts illustrating an example of a manufacturing method of an electronic (EL) device. FIG. 2A is a cross-sectional view illustrating a configuration example of the EL device of the first embodiment, and FIG. 2B is a cross-sectional view illustrating a configuration example midway through the manufacture of the EL device of the first embodiment. FIG. 3 is a cross-sectional view illustrating a non-active region NA of the EL device.

As illustrated in FIGS. 1A and 2A, first a resin layer 12 is formed on a base material 10 (step 51). Next, a barrier layer 3 is formed (step S2). Next, a thin film transistor (TFT) layer 4 that includes a gate insulating film 16, passivation films 18, 20, and an organic flattening film 21 is formed (step S3). Next, a light emitting element layer (OLED element layer, for example) (light emitting element) 5 is formed (step S4). Next, a sealing layer 6 that includes a first inorganic sealing film 26, a second inorganic film 28 and an organic sealing film 27 is formed, establishing a layered body 7 (step S5). Next, the base material 10 and the layered body 7 are divided into individual pieces (step S7). Next, a functional film 39 is adhered via an adhesive layer 38 (step S8).

Next, another electronic circuit substrate is mounted on a terminal TM (connection terminal) positioned on an end portion of the TFT layer 4 illustrated in FIG. 3 (step S9). Thus, the structure of an EL device 2 illustrated in FIGS. 2A and 2B is completed. Note that each of the steps is performed by an EL device manufacturing device 70 described later.

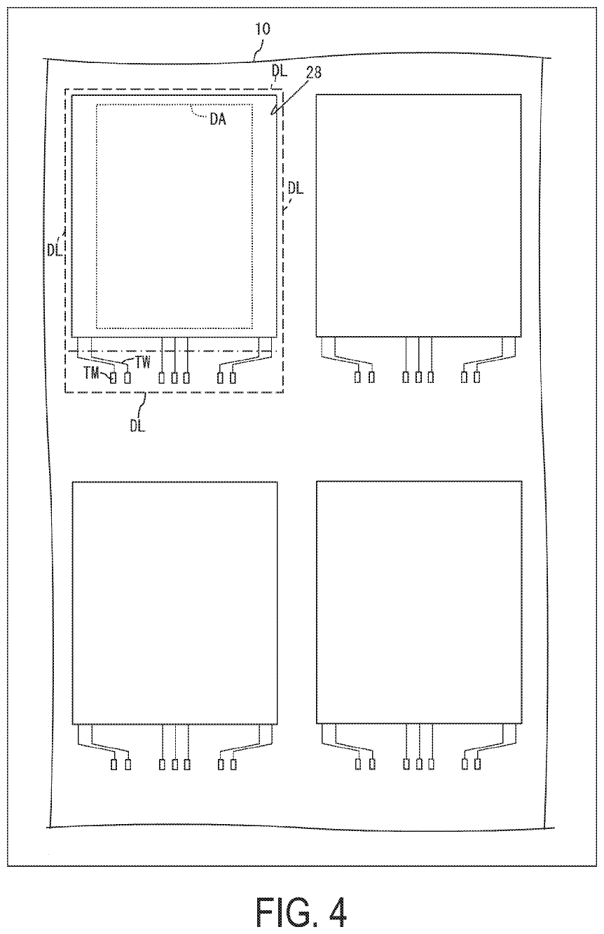

FIG. 4 is a plan view illustrating a plurality of the EL devices 2 formed into a matrix on a surface of the base material 10. After step 9, the base material 10 is divided along a dividing line DL, thereby obtaining the EL devices 2.

Note that, when an EL device having flexibility is manufactured, the layered body 7 (the resin layer 12, the barrier layer 3, the TFT layer 4, the light emitting element layer 5, and the sealing layer 6) is formed on a glass substrate 50, and then an upper face film 9 is adhered onto the layered body 7 via an adhesive layer 8, as illustrated in FIGS. 1B and 2B, for example (step S6a). Next, a laser light is irradiated across the glass substrate 50 onto a lower face of the resin layer 12 (step S6b). Here, the lower face (interface with the glass substrate 50) of the resin layer 12 changes in quality due to ablation, and a bonding force between the resin layer 12 and the glass substrate 50 decreases. Next, the glass substrate 50 is peeled away from the resin layer 12 (step S6c). Next, a base material (a lower face film made from polyethylene terephthalate (PET) or the like, for example) is adhered to the lower face of the resin layer 12 via an adhesive layer (step S6d). Subsequently, the flow transitions to the above-described step S7.

Examples of the materials of the resin layer 12 include a polyimide, an epoxy, and a polyamide.

The barrier layer 3 is a layer that prevents moisture and impurities from reaching the TFT layer 4 and the light emitting element layer 5 during EL device 2 usage, and may include a silicon oxide film, a silicon nitride film, a silicon oxynitride film, or a layered film thereof.

The TFT layer 4 includes a semiconductor film 15, the gate insulating film 16 formed above the semiconductor film 15, a gate electrode G formed above the gate insulating film 16, the passivation films 18, 20 formed above the gate electrode G, a capacitance electrode C and the terminal TM formed above the passivation film 18, a source wiring S and a drain wiring D formed above the passivation film 20, and the organic flattening film (flattening film) 21 formed above the source wiring S and the drain wiring D. A thin layer transistor (TFT) is configured to include the semiconductor film 15, the gate insulating film 16, and the gate electrode G.

As illustrated in FIG. 3, a plurality of the terminals TM used for connection with the electronic circuit substrate are formed in the non-active region NA of the TFT layer 4. The electronic circuit substrate mounted on the plurality of terminals TM is, for example, an integrated circuit (IC) chip or a flexible printed circuit board (FPC). The terminals TM are connected with the electronic circuit of an active region DA by a wiring TW.

The semiconductor film 15 includes a low-temperature polysilicon (LTPS) or an oxide semiconductor, for example. The gate insulating film 16 may be composed of a silicon oxide (SiOx) film or a silicon nitride (SiNx) film formed by chemical vapor deposition (CVD), or a layered film thereof, for example. The gate electrode G, the source electrode S, the drain electrode D, and the terminals include a single layer film of a metal or a layered film including at least one of aluminum (Al), tungsten (W), molybdenum (Mo), tantalum (Ta), chrome (Cr) titanium (Ti), and copper (Cu). Note that while the TFT having the semiconductor film 15 as a channel is illustrated with a top gate structure in FIGS. 2A and 2B, the TFT may have a bottom gate structure (when the TFT channel is an oxide semiconductor, for example).

The gate insulating film 16 and the passivation films 18, 20 may be composed of a silicon oxide (SiOx) film or a silicon nitride (SiNx) film formed by CVD, or a layered film thereof, for example. The organic flattening film 21 may include an applicable photosensitive organic material, such as a polyimide or an acrylic, for example.

The light emitting element layer 5 (an organic light emitting diode layer, for example) includes a first electrode 22 (anode electrode, for example) formed above the organic flattening film 21, an organic insulating film 23 that covers an edge of the first electrode 22, an EL layer 24 formed above the first electrode 22, and a second electrode 25 formed above the EL layer 24. The light emitting element (organic light emitting diode, for example) includes the first electrode 22, the EL layer 24, and the second electrode 25. The organic insulating film 23 of the active region DA functions as a bank (pixel partition) that regulates subpixels.

The organic insulating film 23 may include an applicable photosensitive organic material, such as a polyimide or an acrylic, for example. The organic insulating film 23 may be applied by an inkjet method to the active region DA and the non-active region NA, for example.

The non-active region NA is provided with a convex body TK that has a bank shape and surrounds the active region. The convex body TK regulates an edge of the organic sealing film 27. The convex body TK is configured to include at least one of the organic flattening film 21 and the organic insulating film 23, for example.

The EL layer 24 is formed by vapor deposition or an inkjet method in a region (subpixel region) surrounded by the partition made from the organic insulating film 23. When the light emitting element layer 5 is an organic light emitting diode (OLED) layer, the EL layer 24 is, for example, configured by layering a hole injecting layer, a hole transport layer, a light emitting layer, an electron transport layer, and an electron injecting layer, in that order from a lower layer side. Note that one or more layers of the EL layer 24 can be established as a common layer (common to the plurality of pixels).

The first electrode (positive electrode) 22 is configured by layering indium tin oxide (ITO) and an alloy that includes Ag, for example, and thus has optical reflectivity. The second electrode (a cathode electrode, for example) 25 is a common electrode, and includes a transparent metal, such as ITO or indium zincum oxide (IZO).

When the light emitting element layer 5 is an OLED layer, the electrons recombine with the electron holes in the EL layer by a drive current between the first electrode 22 and the second electrode 25, causing excitons produced thereby to drop to a ground state, emitting light.

The light emitting element layer 5 is not limited to constituting an OLED element, and may constitute an inorganic light emitting diode or a quantum dot light emitting diode.

The sealing layer 6 covers the light emitting element layer 5, and prevents penetration of foreign matter such as water or oxygen into the light emitting element layer 5. The sealing layer 6 includes the first inorganic sealing film 26 that covers the organic insulating film 23 and the second electrode 25, the organic sealing film 27 that is formed above the first inorganic sealing film 26 and functions as a buffer film, and the second inorganic sealing film 28 that covers the first inorganic sealing film 26 and the organic sealing film 27.

The first inorganic sealing film 26 and the second inorganic sealing film 28 may each be composed of a silicon oxide film, a silicon nitride film, a silicon oxynitride film, or a layered film thereof formed by CVD using a mask, for example. The organic sealing film 27 is a transparent organic insulating film thicker than the first inorganic sealing film 26 and the second inorganic sealing film 28, and may include an applicable photosensitive organic material, such as a polyimide or an acrylic, for example. For example, after ink that includes such an organic material is applied by inkjet onto the first inorganic sealing film 26, the ink is cured by ultraviolet (UV) irradiation.

The functional film 39 includes, for example, an optical compensation function, a touch sensor function, a protection function, and the like. When a layer having one or more of these functions is layered above the light emitting element layer 5, the functional film 39 can be thinned or removed.

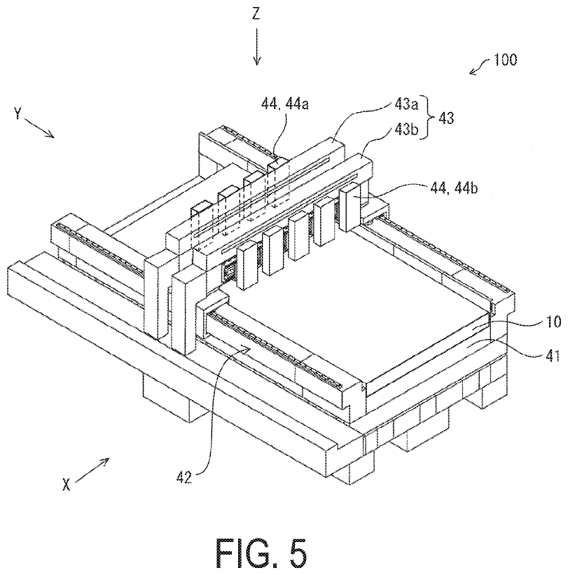

FIG. 5 is a perspective view illustrating an outer appearance of a film formation device 1 according to the present embodiment. The film formation device 1, in step S5 illustrated in FIG. 1A, ejects a droplet material (ink), thereby forming the organic sealing film 27 of the EL device 2.

The film formation device 1 includes a stage 41 configured to mount the base material 10, and a gantry 43 that crosses above the stage 41. The gantry 43 can move back and forth in direction Y in FIG. 5 by a gantry slide mechanism 42 connected to the stage 41. The gantry 43 changes position with respect to the stage 41, making it possible to eject ink to a preferred region of the base material 10 mounted on the stage 41. The plurality of EL devices 2 midway through manufacture are formed in direction Y on the base material 10. The film formation device 1 ejects ink to each of these EL devices 2 midway through manufacture.

The gantry 43 includes a pair of gantry units 43a, 43b disposed parallel to each other. A plurality of ejecting portions 44 are mounted in rows on side faces of the gantry units 43a, 43b. An ejecting portion 44a (first ejecting portion) of the gantry unit 43a and an ejecting portion 44b (second ejecting portion) of the gantry unit 43b have the same structure, but eject different types of inks. In the description below, when a distinction does not need to be made, the ejecting portions 44a, 44b are simply referred to as the ejecting portions 44.

The number of the ejecting portions 44 of the gantry units 43a, 43b is not particularly limited, and may be one. The number of the ejecting portions 44 may be determined in accordance with the number of the EL devices 2 that are formed into one base material 10. In the example illustrated in FIG. 5, four ejecting portions 44a are mounted to the gantry unit 43a, and five ejecting portions 44b are mounted to the gantry unit 43b. The organic sealing film 27 formed by the ejecting portions 44b is formed on an outer periphery portion of the organic sealing film 27 formed by the ejecting portions 44a. As a result, the mounted number of ejecting portions 44b is greater than the mounted number of ejecting portions 44a, expanding the applicable region of the ejecting portions 44b.

Note that the gantry 43 does not necessarily need to include the plurality of gantry units 43a, 43b, and may include only one gantry unit. In this case, both of the ejecting portions 44a, 44b are mounted on the one gantry unit. As described later, as long as a slide mechanism 58 (refer to FIG. 7) that moves the ejecting portions 44a, 44b in direction X is set, the ink ejected from the ejecting portions 44a, 44b can be applied to a preferred region even when both of the ejecting portions 44a, 44b are mounted to one gantry unit.

Further, in the film formation device 1, the stage 41 on which the base material 10 is mounted may be configured to move with respect to the gantry 43. As long as the relative positional relationship between the base material 10 and the ejecting portions 44 can change, either the stage 41 or the gantry 43 may be moved.

The ink (first droplet material; referred to as an ink A) ejected by the ejecting portions 44a has a low viscosity and readily spreads on a surface (has a high wettability). The viscosity of the ink A is preferably 4 Pa·s or greater and less than 20 Pa·s.

The ink (second droplet material; referred to as an ink B) ejected by the ejecting portions 44b has a high viscosity and a low wettability. The viscosity of the ink B is preferably 10 Pa·s or greater and no greater than 40 Pa·s. The viscosities of the inks A and B described here refer to viscosities at room temperature.

The ink A used can be an ink having an acrylic resin composition or an epoxy resin composition, for example.

The ink B used can be an ink having a composition similar to that of the ink A or a composition different from that of the ink A, for example.

Conceivable compositions used include (1) an acrylic resin (10 Pa·s) as the ink A, and an acrylic resin (20 Pa·s) as the ink B, and (2) an acrylic resin (20 Pa·s) as the ink A, and an epoxy resin (30 Pa·s) as the ink B.

The ejecting portion 44a ejects the ink A onto a region corresponding to a center portion of the active region DA of the EL device 2, on the surface of the first inorganic sealing film 26. The active region DA corresponds to a region where the light emitting element layer 5 is formed, and can be expressed as a display region.

The ejecting portion 44b ejects the ink B onto a region corresponding to an edge portion of the EL device 2 on the surface of the first inorganic sealing film 26. The edge portion is an outer edge portion of the active region DA, and includes a portion of the non-active region NA. The active region DA does not need to be included in the application region of the ink B.

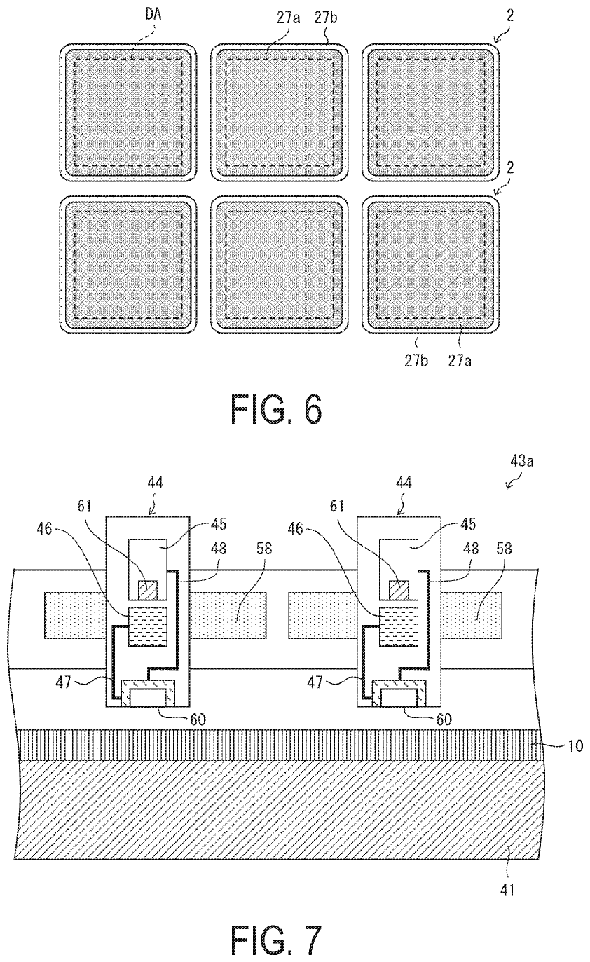

FIG. 6 is a diagram illustrating the application regions of the ink A and the ink B. The organic sealing film 27 formed by applying the ink A is called a first film 27a, and the organic sealing film 27 formed by applying the ink B is called the second film 27b. The ink A and the ink B are ejected so that the first film 27a and the second film 27b are adjacent (adjacent within the same layer) in a direction along a substrate surface of the EL device 2. More specifically, the second film 27b formed surrounding at least a portion of an outer periphery of the first film 27a. The first film 27a is mainly formed in the active region DA, and the second film 27b is, for example, formed in a boundary portion between the active region DA and the non-active region NA. Note that the active region DA is covered by the first film 27a, and is thus indicated in FIG. 6 by the dashed line.

FIG. 3 illustrates the first film 27a formed on the side of the active region DA, and the second film 27b formed on the side of the non-active region NA. The first film 27a and the second film 27b form the same organic sealing film 27.

When the organic sealing film 27 is formed by the inkjet method, the organic sealing film 27 is required not to extend over the convex body TK having a frame shape and surrounding the active region DA (display region), as illustrated in FIG. 3.

A plurality of the terminals TM (connection terminals) used for connection with another electronic circuit substrate (an IC chip, for example; second circuit substrate) are formed on an outer side of the convex body TK. When the terminals TM are covered by the organic sealing film 27, the electronic circuit substrate (first circuit substrate) and another electronic circuit substrate can no longer be conductively connected. Thus, it is important to form the organic sealing film 27 on an inner side (active region DA side) of the convex body TK.

In the present embodiment, the ejecting portion 44a ejects the ink A having a low viscosity near the center of the active region DA, thereby promptly forming the organic sealing film 27. On the other hand, the ejecting portion 44b ejects the ink B having a high viscosity on the display region side of the convex body TK, near the boundary between the active region DA and the non-active region NA, thereby forming the second film 27b. With this configuration, the possibility that the ink B will extend over the convex body TK decreases, making it possible to form the organic sealing film 27 with a sharp edge.

While a plurality of the convex bodies TK may conceivably be formed to ensure that the organic sealing film 27 does not extend over the convex body TK, use of the ink B makes it possible to achieve the object without increasing the number of convex bodies TK.

Further, even when the convex body TK does not exist, a formation range of the organic sealing film 27 can be clearly regulated by forming an outer frame of the organic sealing film 27 using the second film 27b.

Note that, when the region where the organic sealing film 27 is formed is regarded as a rectangle, the ink B does not need to be applied to all four sides of the rectangle, and may be applied only to one side of the rectangle.

The order of ejecting the inks A and B is not particularly limited. To clearly regulate the film formation range of the organic sealing film 27 by the ink A, preferably the ink B is ejected at the same time as or before the ink A. After ink ejection, leveling of about 0 to 300 s is performed, followed by a UV hardening process. When the ink A is first ejected in the center portion of the active region DA having a low viscosity and a favorable wettability, the ink more readily spreads on the surface, making the ink more susceptible to protrusion and the like. Comprehensively, taking tack into consideration, the method of ejecting the inks A, B simultaneously from the ejecting portions 44a and the ejecting portions 44b is preferred.

After the second film 27b is formed into a frame shape along the convex body TK by ejecting the ink B by the ejecting portions 44b, the first film 27a may be formed on the inner side thereof by ejecting the ink A by the ejecting portions 44a. That is, the film formation method of the present embodiment may include a first application step of ejecting the ink B by the ejecting portions 44b, thereby forming the second film 27b into a frame shape, and a second application step of ejecting the ink A by the ejecting portions 44a, thereby forming the first film 27a on the inner side of the second film 27b having a frame shape. With this configuration, the formation range of the first film 27a can be regulated by the second film 27b having a frame shape, making it easier to define the formation range of the organic sealing film 27 to a preferred range.

Here, presume that there is a line on the surface of the base material 10 parallel to direction X, having a specific coordinate Y. The ink B is applied before the ink A on the one line of interest while moving the gantry units 43a, 43b in direction Y in FIG. 5, as long as ink is ejected from the gantry units 43a, 43b.

The configuration may be such that one each of the ejecting portions 44a, 44b are mounted on one of the gantry units 43. In such a configuration, when the ejecting portions 44a, 44b are moved across the base material 10 in a width direction of the base material 10, along the gantry unit 43, the ejecting portion 44b moves and ejects the ink B first.

An ejecting amount of the ink per unit surface area is preferably the same for the ink A and the ink B, and a film thickness of the organic sealing film 27 is about from 1 to 20 μm, for example. The ejection pattern of the ink B may be adjusted by narrowing (high-density application) or widening (low density application) an application pitch, changing the single droplet amount, or the like.

FIG. 7 is a cross-sectional view of the ejecting portions 44 of the film formation device 1. The slide mechanism 58 capable of moving the ejecting portion 44 in a direction (direction X in FIGS. 1A and 1B) orthogonal to a movement direction (direction Y in FIGS. 1A and 1B) of the gantry units 43a, 43b is mounted on a side face of the gantry units 43a, 43b. As a result, the ejecting portion 44 is capable of moving in the width direction of the base material 10. With this configuration, there is no longer a need to create a one-to-one correspondence between the ejecting portion 44 and an ink ejecting target area (a portion of the EL device 2), making it possible to eject ink onto a plurality of locations of the EL device 2 using a single ejecting portion 44.

The ejecting portion 44 includes on a tip portion on a side facing the stage 41 a head unit 60 provided with a nozzle hole 49 that ejects droplets.

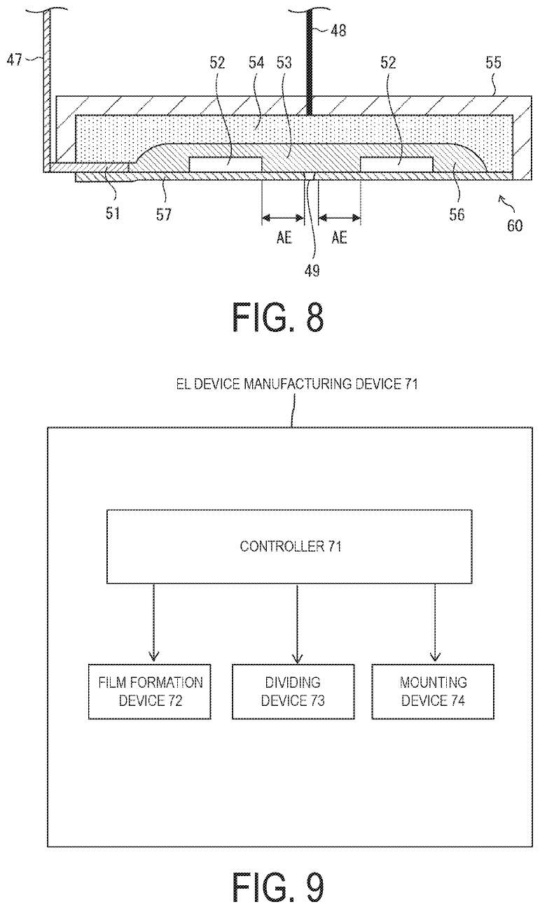

The ink A (or the ink B) is supplied to the head unit 60 from an ink tank 45 via an ink pipe 48. The head unit 60 ejects the ink A (or the ink B) from the nozzle hole 49 in accordance with a control signal output from a drive control circuit 46. The control signal that indicates the timing of ink ejection is transmitted from a controller 71 (refer to FIG. 8) to the drive control circuit 46.

FIG. 8 is a cross-sectional view of the head unit 60. As illustrated in FIG. 8, the head unit 60 is a top shooter type inkjet head unit, is formed on an inner side of a base member 55, and mainly includes a piezoelectric substrate 54 polarized in a substrate thickness direction, and a nozzle plate 57 connected to the piezoelectric substrate 54. A plurality of the nozzle holes 49 are formed in the nozzle plate 57. However, in FIG. 8, the nozzle holes 49 are arranged side-by-side in a direction orthogonal to the paper surface, and thus only one is illustrated.

A plurality of ink chambers 53 having a slender shape are formed by dicing in the piezoelectric substrate 54, and a shallow groove portion 51 is formed at an end portion of each of the ink chamber 53. The ink chambers 53 are also arranged side-by-side in the direction orthogonal to the paper surface in FIG. 8.

An electrode 56 is formed on an inner wall surface of the ink chamber 53 and the shallow groove portion 51, and the electrode 56 drawn to the shallow groove portion 51 is connected to a terminal 47 of the drive control circuit 46.

In each of the ink chambers 53, a common ink chamber 52 is formed on both sides of the nozzle hole 49 in a longitudinal direction of the ink chamber 53. The common ink chamber 52 communicates with the common ink chamber 52 of another ink chamber 53 adjacent thereto and formed in a direction orthogonal to the longitudinal direction of the ink chamber 53. The ink is supplied to the common ink chamber 52 of each of the ink chambers 53.

When voltage is applied to the electrode 56 of each of the ink chambers 53 from the drive control circuit 46, an inner wall of the ink chamber 53 deforms, protruding toward an outer side and pressurizing the ink inside the ink chamber 53. As a result, ink is ejected from the nozzle holes 49.

A region that contributes to the ejection of ink is referred to as an active area, and this active area AE is provided to both sides of the nozzle hole 49 in the top shooter type head unit 60. In such a head unit 60, an applied pressure of the ink and a dispensed ink droplet amount can be controlled by increasing and decreasing the voltage and thus controlling the deformation of a piezoelectric substance, facilitating gray scale printing.

While, in the embodiment described above, the film formation device 1 forms the organic sealing film 27, the film formation device 1 may form an organic film (the organic insulating film 23, for example) other than the organic sealing film 27. Further, the film formation device 1 may be realized as a film formation device that forms an organic film on a surface of an object to be coated that differs from the EL device 2.

### Second Embodiment

Another embodiment of the disclosure will be described below. Note that, for the convenience of explanation, members having the same function as those of members described in the above embodiment will be denoted using the same reference numerals, and descriptions thereof will be omitted.

The ink B has a higher viscosity than that of the ink A, and thus it is important to devise a way to make the droplet ejecting pressure of the ejecting portion 44b greater than the droplet ejecting pressure of the ejecting portion 44a. In the present embodiment, a method of stably ejecting the ink B having a high viscosity will be described.

To ensure that the droplets land on the application target with favorable accuracy, the droplets ejected from the nozzle holes 49 preferably have a velocity of a certain degree or greater. When the velocity is excessive, the ejection becomes unstable. The preferred velocity of the droplets is from 7 to 15 m/s. When the ink viscosity is high, flow path resistance increases accordingly. Thus, the velocity of the droplets of the ink B becomes less than the velocity of the ink A when the same ejecting portion 44 as that for the ink A is used and the voltage applied to the piezo elements is made the same, making it no longer possible to form a film in the preferred location. To solve this problem, the following methods (1) to (3) are conceivable.

(1) The applied voltage when the ink B is ejected is made greater than the applied voltage when the ink A is ejected.

(2) The structure (length of the active area AE, etc.) of the ejecting portion 44 is changed.

(3) The temperature of the ink is changed.

According to the method (1), increasing the applied voltage when the ink B is ejected increases the droplet ejecting pressure of the ejecting portion 44b, making it possible to stably eject the ink B having a high viscosity at substantially the same velocity as that of the ink A. Further, with the velocities of the droplets of the inks A, B made substantially the same, the droplets can be made to land in preferred locations with favorable accuracy. Furthermore, according to the method (1), the volumes of the ink ejected from the ejecting portion 44a and the ejecting portion 44b can be made the same. Note that making the velocities of the droplets substantially the same means that the difference between the velocities of the droplets of the inks A, B is within ±2 m/s.

Specific examples of the method (2) include shortening a length of the active area AE near the nozzle holes 49 of the ejecting portion 44b illustrated in FIG. 8 (the distance from the nozzle holes 49 to the common ink chamber 52) further than the length of the ejecting portion 44a. With this configuration, the droplet ejecting pressure of the ejecting portion 44b increases, making it possible to increase the velocity of the droplets of the ink B having a high viscosity. However, because increasing the length of the active area AE (decreasing the size of the nozzle hole 49) decreases the amount of ink that swells on the nozzle hole 49 due to surface tension, and the amount of ink retained in the nozzle hole 49 is small, the droplet ejecting pressure may increase.

Further, a diameter of the nozzle hole 49 of the ejecting portion 44b may be greater than a diameter of the nozzle hole 49 of the ejecting portion 44a.

According to method (2), the channel structure is physically changed, making it possible to make the velocities of the droplets of the inks A and B substantially the same upon making the applied voltage of the ejecting portion 44a and the ejecting portion 44b the same.

Specific examples of the method (3) include providing a heater 61 configured to heat the ink B to the ejecting portion 44b to temporarily decrease the viscosity of the ink B at the time of ejection. When the temperature of the ink B is too high, the viscosity of the ink B becomes excessively low, causing failure to realize the preferred function of the ink B, that is, regulation of the formation range of the organic sealing film 27. Thus, preferably the temperature of the ink B is set to a temperature within a range that allows the ink B to be smoothly ejected at the time of ejection, and yet quickly decrease to room temperature upon landing.

The installation location of the heater 61 is not particularly limited as long as the location allows heating of the ink B and, as illustrated in FIG. 7, is the interior of the ink tank 45, for example.

According to the method (3), the viscosity of the ink B is temporarily decreased during ejection, thereby increasing the velocity of the droplets of the ink B and making it possible to make the droplets land in the preferred location with favorable accuracy.

Note that, to increase the degree of freedom of adjustment of droplet velocity, the methods (1) to (3) may be combined.

### Third Embodiment

FIG. 9 is a block diagram illustrating a configuration of an EL device manufacturing device 70 of the present embodiment. As illustrated in FIG. 9, the EL device manufacturing device 70 includes a film formation device 72, a dividing device 72, a mounting device 74, and the controller 71 that controls these devices. The film formation device 1 is included as the one film formation device 72 in the EL device manufacturing device 70. The film formation device 1 that receives control of the controller 71 performs the processing of step S5 in FIG. 1A.

Thus, the EL device manufacturing device 70 that includes the film formation device 1 is also included in the technical scope of the disclosure.

### Supplements

A film formation device according to a first aspect is based on an inkjet method, and includes a first ejecting portion configured to eject a first droplet material, and a second ejecting portion configured to eject a second droplet material having a viscosity greater than a viscosity of the first droplet material. The first and the second droplet materials, upon ejection, form a first film formed by application of the first droplet material and a second film formed by application of the second droplet material, the first film and the second film being adjacent to each other on a surface of an object to be coated.

With the above configuration, the spread of the first droplet material outside a predetermined region after application can be regulated by the second droplet material having a viscosity greater than the viscosity of the first droplet material, making it possible to control the formation range of a film by the inkjet method.

According to a second aspect, the second film may be formed surrounding at least a portion of an outer periphery of the first film.

With the above configuration, the formation range of the first film can be more effectively regulated.

According to a third aspect, the object includes a circuit having a connection terminal, the second film is formed between the first film and the connection terminal, and the first and the second droplet materials are ejected in a manner that prevents the second film from covering the connection terminal.

With the above configuration, when a circuit substrate conductively connectable with another circuit substrate via a connection terminal is manufactured, the spread of the first droplet material having a low viscosity to the connection terminal can be prevented by the second film formed by the second droplet material having a high viscosity.

According to a fourth aspect, the viscosity of the first droplet material may be from 4 Pa·s to 20 Pa·s, both inclusive, and the viscosity of the second droplet material may be from 10 Pa·s to 40 Pa·s, both inclusive.

According to a fifth aspect, the second ejecting portion has an ejecting pressure greater than an ejecting pressure of the first ejecting portion.

With the above configuration, the second droplet material having a high viscosity can be smoothly ejected.

According to a sixth aspect, a velocity of droplets ejected from the first ejecting portion may be substantially identical to a velocity of droplets ejected from the second ejecting portion.

With the above configuration, it is possible to increase a landing accuracy of the droplets.

According to a seventh aspect, the object to be coated may include a thin film transistor layer, a light emitting element, and an inorganic sealing film formed on the light emitting element, and the first film and the second film may be formed by ejecting the first droplet material and the second droplet material onto the inorganic sealing film.

With the above configuration, it is possible to form the first film and the second film on an inorganic sealing film of a device including a light emitting element.

According to an eighth aspect, a convex body having a frame shape may be formed surrounding a display region where the light emitting element is formed. In such a configuration, the second ejecting portion may form the second film by ejecting the second droplet material onto the display region side of the convex body.

With the above configuration, it is possible to form the second film with the second film surrounding the display region in a planar view of the substrate.

According to a ninth aspect, the second ejecting portion may form the second film into a frame shape along the convex body, and then the first ejecting portion may form the first film on an inner side of the second film having the frame shape.

According to the above configuration, after the second film is formed surrounding the display region, the first film is formed on the inner side thereof, making it possible to regulate the formation range of the first film by the second film. As a result, it is easy to establish the relative positions of the display region and the first and second films as desired.

A manufacturing device of an electronic device that includes the film formation device is also included in the technical scope of the disclosure.

A film formation method according to an eleventh aspect is based on an inkjet method, and includes a first ejecting step of ejecting a first droplet material, and a second ejecting step of ejecting a second droplet material having a viscosity greater than a viscosity of the first droplet material. The first and the second droplet materials, upon ejection, form a first film formed by application of the first droplet material and a second film formed by application of the second droplet material, the first film and the second film being adjacent to each other on a surface of an object to be coated.

With the above configuration, the spread of the first droplet material outside a predetermined region after application can be regulated by the second droplet material having a viscosity greater than the viscosity of the first droplet material, making it possible to control the formation range of a film by the inkjet method.

An electronic device according to a twelfth aspect includes a first circuit substrate provided with a first film formed by applying a first droplet material and a second film formed by applying a second droplet material having a viscosity greater than a viscosity of the first droplet material, the first film and the second film being formed adjacent to each other in a direction on a surface.

According to a thirteenth aspect, the electronic device further includes a second circuit substrate. In such a configuration, the first circuit substrate includes a connection terminal, the second circuit substrate is connected to the first circuit substrate via the connection terminal, and the second film is formed between the first film and the connection terminal without covering the connection terminal.

As a result, the first circuit substrate and the second circuit substrate can be conductively connected via the connection terminal.

According to a fourteenth aspect, the first circuit substrate may further include a thin film transistor layer, a light emitting element, and an inorganic sealing film formed on the light emitting element. The first film and the second film may be formed on the inorganic sealing film.

With the above configuration, it is possible to form the first film and the second film on an inorganic sealing film of a device including a light emitting element.

According to a fifteenth aspect, a convex body having a frame shape may be formed surrounding a display region where the light emitting element is formed, and the second film may be formed on the display region side of the convex body.

With the above configuration, it is possible to form the second film surrounding the display region in a planar view of the first circuit substrate.

The disclosure is not limited to each of the embodiments stated above, and various modifications may be implemented within a range not departing from the scope of the claims. Embodiments obtained by appropriately combining technical approaches stated in each of the different embodiments also fall within the scope of the technology of the disclosure. Moreover, novel technical features may be formed by combining the technical approaches stated in each of the embodiments.

### REFERENCE SIGNS LIST

1 Film formation device
2 EL device
4 TFT layer (thin film transistor layer)
5 Light emitting element layer (light emitting element)
10 Base material
24 EL layer
26 First inorganic sealing film
27 Organic sealing film (first film, second film)
44a Ejecting portion
44b Ejecting portion
TM Terminal (connection terminal)
70 EL device manufacturing device

1. A film formation device based on an inkjet method, comprising:
a first ejecting portion configured to eject a first droplet material; and
a second ejecting portion configured to eject a second droplet material having a viscosity greater than a viscosity of the first droplet material,
wherein the first and the second droplet materials, upon ejection, form a first film formed by application of the first droplet material and a second film formed by application of the second droplet material, the first film and the second film being adjacent to each other on a surface of an object to be coated,
the object to be coated includes a thin film transistor layer, a light emitting element, and an inorganic sealing film formed on the light emitting element,
the first film and the second film are formed by ejecting the first droplet material and the second droplet material onto the inorganic sealing film,
a convex body having a frame shape is formed surrounding a display region where the light emitting element is formed, and
the second ejecting portion forms the second film by ejecting the second droplet material onto the display region side of the convex body.

2. The film formation device according to claim 1,
wherein the second film is formed surrounding at least a portion of an outer periphery of the first film.

3. The film formation device according to claim 1,
wherein the object includes a circuit having a connection terminal,
the second film is formed between the first film and the connection terminal, and
the first and the second droplet materials are ejected in a manner that prevents the second film from covering the connection terminal.

4. The film formation device according to claim 1,
wherein the viscosity of the first droplet material is from 4 Pa·s to 20 Pa·s, both inclusive, and the viscosity of the second droplet material is from 10 Pa·s to 40 Pa·s, both inclusive.

5. The film formation device according to claim 1,
wherein the second ejecting portion has an ejecting pressure greater than an ejecting pressure of the first ejecting portion.

6. The film formation device according to claim 1,
wherein a velocity of droplets ejected from the first ejecting portion is substantially identical to a velocity of droplets ejected from the second ejecting portion.

7-8. (canceled)

9. The film formation device according to claim 1,
wherein the second ejecting portion forms the second film into a frame shape along the convex body, and then the first ejecting portion forms the first film on an inner side of the second film having the frame shape.

10. A manufacturing device of an electronic device that includes the film formation device described in claim 1.

11. (canceled)

12. An electronic device comprising:
a first circuit substrate provided with a first film formed by applying a first droplet material and a second film formed by applying a second droplet material having a viscosity greater than a viscosity of the first droplet material, the first film and the second film being formed adjacent to each other in a direction along a substrate surface,
wherein the first circuit substrate includes a thin film transistor layer, a light emitting element, and an inorganic sealing film formed on the light emitting element,
the first film and the second film are formed on the inorganic sealing film,
a convex body having a frame shape is formed surrounding a display region where the light emitting element is formed, and
the second film is formed on the display region side of the convex body.

13. The electronic device according to claim 12, further comprising:
a second circuit substrate,
wherein the first circuit substrate includes a connection terminal,
the second circuit substrate is connected to the first circuit substrate via the connection terminal, and
the second film is formed between the first film and the connection terminal without covering the connection terminal.

14-15. (canceled)
